(19) United States
(12) Patent Application Publication
(10) Pub. No.: US 2024/0064910 A1
(43) Pub. Date: Feb. 22, 2024

(54) LAMINATE COATED WITH ASYMMETRIC METAL FOILS, AND PRINTED CIRCUIT BOARD INCLUDING SAME

(71) Applicant: SHENGYI TECHNOLOGY CO., LTD., Dongguan, Guangdong Province (CN)

(72) Inventors: Junqi TANG, Dongguan (CN); Zhiguang LI, Dongguan (CN)

(21) Appl. No.: 18/270,038

(22) PCT Filed: Jan. 8, 2021
(86) PCT No.: PCT/CN2021/070942

§ 371 Date: Jun. 28, 2023

(30) Foreign Application Priority Data
Dec. 29, 2020 (CN) 202011587807.1

(51) Int. Cl. H05K 3/46; H05K 1/03

(52) U.S. Cl. CPC H05K 3/4652; H05K 3/4632; H05K 1/0306; H05K 2201/0278

(57) ABSTRACT

A laminate coated with asymmetric metal foils, and a printed circuit board including same. The laminate comprises one or at least two stacked low-modulus prepregs, and a metal foil, coated on one side of the one or at least two stacked low-modulus prepregs, or metal foils having different thicknesses coated on two sides of the one or at least two stacked low-modulus prepregs. The modulus of elasticity of the low-modulus prepreg is 22 GPa or less after the low-modulus prepreg is cured. A low-modulus prepreg having a modulus of elasticity of 22 GPa or less after curing is selected as an insulating material for a laminate coated with asymmetric metal foils, such that the resultant laminate and a printed circuit board manufactured therefrom have a relatively low A-state warpage and a warpage which is obtained after reflow soldering processing, thereby ensuring the reliability of the printed circuit board.

### TECHNICAL FIELD

The present application belongs to the technical field of circuit boards, and in particular to a laminate coated with asymmetric metal foils, and a printed circuit board including the same.

### BACKGROUND

Printed circuit boards are a support body of electronic components, and are a provider of electrical connection of electronic components, which are widely used in a variety of electronic equipments, communication equipments, computers, automobiles, household appliances and other equipment. With the development of electronic information technology and the multi-functionality and miniaturization of electronic products, its core skeleton integrated circuit board gradually tends to multi-layered and multi-functional.

The laminate coated with metal foils is a basic material for producing printed circuit boards. Both sides of the conventional double-sided laminate coated with metal foils are coated with metal foils having the same thickness and consistent characteristics. Even if the metal foils on the two sides are different, their thicknesses and characteristics will be not much different, so that the double-sided laminate coated with metal foils has a low warpage in A-state and after reflow soldering treatment, or even no warpage, ensuring that the printed circuit board has a good carrying capacity for electronic components.

Single-sided circuit boards require to coat with a copper plate on the one side; in a case where the single-sided circuit require to pass high current, it is necessary to design metal foils with different thicknesses on both sides of the double-sided laminate coated with metal foils, which can not only meet the requirements of performance and cost reduction, but also meet the heat dissipation requirements of the circuit under high current. However, the asymmetrical structure of the metal foil will lead to uneven internal stress generated by the laminate coated with asymmetric metal foils during the processing process, such as lamination, weld and hot air leveling, resulting in warpage of the laminate and the printed circuit board prepared by it, and further causing the installation failure of electronic components, circuit short out and other reliability reduction problems.

Therefore, it is necessary to develop a laminate coated with asymmetric metal foils with a low warpage to improve the reliability of the printed circuit board prepared by it.

### SUMMARY

In view of the deficiencies of the prior art, an object of the present application to provide a laminate coated with asymmetric metal foils, and a printed circuit board including the same. The laminate coated with asymmetric metal foils has a relatively low A-state warpage and a relatively low warpage after reflow soldering, which is conducive to improving the safety and reliability of the printed circuit board.

To achieve the above object, the present application adopts the technical solutions below.

In a first aspect, the present application provides a laminate coated with asymmetric metal foils, which includes one or at least two stacked low-modulus prepregs, and a metal foil which is coated on one side of the one or at least two stacked low-modulus prepregs or metal foils having different thicknesses which are coated on two sides of the one or at least two stacked low-modulus prepregs;
a modulus of elasticity of the cured low-modulus prepreg is less than or equal to 22 GPa (for example, it may be 22 GPa, 21.5 GPa, 21 GPa, 20.5 GPa, 20 GPa, 19.5 GPa, 19 GPa, 18.5 GPa, 18 GPa, 17.5 GPa, 17 GPa, 16.5 GPa, 16 GPa, 15.5 GPa, 15 GPa, 14 GPa, 13 GPa, 12 GPa, 11 GPa, 10 GPa, 8 GPa, 6 GPa, or 5 GPa, etc.).

Through the research, the inventor has found that by selecting a cured low-modulus prepreg with a modulus of elasticity of less than or equal to 22 GPa as an insulation material for the laminate coated with asymmetric metal foils, the laminate can be guaranteed to have a relatively low warpage. If the modulus of elasticity of the cured prepreg is more than 22 GPa, the rigidity of the laminate is too large, the buffer capacity against stress is weak, and the stress caused by an structural asymmetry of the laminate coated with asymmetric metal foils cannot be effectively buffered, resulting in the laminate coated with asymmetric metal foils being prone to warpage.

It should be noted that in the present application, when the laminate includes a low-modulus prepreg, “one or both sides of a low-modulus prepreg” refers to one or both sides of the low-modulus prepreg; when the laminate includes at least two low-modulus prepregs, “one or both sides of a low-modulus prepreg” refers to one or both sides of the stacked low-modulus prepreg composite material. The present application does not limit the thickness of the prepreg. The “asymmetry” in the present application mainly refers to that the thicknesses of metal foils on both sides of the low-modulus prepreg are unequal, including a case where only one side of the low-modulus prepreg is coated with a metal foil, that is, a single panel that one side is coated with a metal foil and the other side has no metal foil, and also including a case where both sides are covered with metal foils that have different thicknesses.

The low-modulus prepreg includes a substrate and a resin composition adhered to the substrate by impregnating or coating. The present application does not specifically limit the type of the resin composition, and those skilled in the art can choose according to actual needs, which meets the modulus of elasticity of the cured low-modulus prepreg of less than or equal to 22 GPa. The present application does not specifically limit the substrate, exemplarily, the substrate may be textiles, non-woven fabrics, rovings, staple fibers, fiber paper, etc., and a material of the substrate may be inorganic fibers (e.g., E-glass, D-glass, L-glass, M-glass, S-glass, T-glass, NE-glass, Q-glass, quartz and other glass fibers) or organic fibers (e.g., polyimide, polyamide, polyester, polyphenylene ether, liquid crystal polymers, etc.), preferably glass fiber cloth.

The present application does not specifically limit the method for preparing the laminate coated with asymmetric metal foils, which can be prepared by a well-known method. Lamination conditions can be general lamination conditions of a laminate coated with metal foil, a laminate for printed circuit boards and a multi-layer board.

The following are preferred technical solutions of the present application, but do not constitute a limitation on the technical solutions provided in the present application; by the following preferred technical solutions, the objects and beneficial effects of the present application can be better achieved.

As a preferred technical solution of the present application, a modulus of elasticity of the cured low-modulus prepreg is less than or equal to 20 GPa.

As a preferred technical solution of the present application, a modulus of elasticity of the cured low-modulus prepreg is less than or equal to 18 GPa.

As a preferred technical solution of the present application, a modulus of elasticity of the cured low-modulus prepreg is less than or equal to 16 GPa.

As a preferred technical solution of the present application, a modulus of elasticity of the cured low-modulus prepreg is more than or equal to 5 GPa. If the modulus of elasticity of the cured low-modulus prepreg is too low, the rigidity of the laminate is too small, when the external force is too large, the laminate coated with asymmetric metal foils may be deformed, and the carrying capacity of the printed circuit board to the electronic components becomes worse; in addition, when the modulus is too low, the manufacture of the printed circuit board also have operational difficulty. According to the application requirements, the appropriate modulus should be selected to prevent the laminate coated with asymmetric metal foils or the printed circuit board from bending, thus resulting in large deformation during use.

As a preferred technical solution of the present application, an XY-CTE (coefficient of thermal expansion in planar direction) of the cured low-modulus prepreg is less than or equal to 18 ppm/° C.; for example, it may be 18 ppm/° C., 17.5 ppm/° C., 17 ppm/° C., 16.5 ppm/° C., 16 ppm/° C., 15.5 ppm/° C., 15 ppm/° C., 14.5 ppm/° C., 14 ppm/° C., 13.5 ppm/° C., 13 ppm/° C., 12.5 ppm/° C., 12 ppm/° C., 11.5 ppm/° C., 11 ppm/° C., 10 ppm/° C., 9 ppm/° C., 8 ppm/° C., 7 ppm/° C., 6 ppm/° C., 5 ppm/° C., 3 ppm/° C. or 1.5 ppm/° C., etc.

As a preferred technical solution of the present application, an XY-CTE of the cured low-modulus prepreg is less than or equal to 16 ppm/° C.

As a preferred technical solution of the present application, an XY-CTE of the cured low-modulus prepreg is less than or equal to 14 ppm/° C.

In the present application, if the XY-CTE of the cured low-modulus prepreg is too high, which is higher than 18 ppm/° C., the deformation is large when the heated laminate is subjected to stress, and the warpage of the laminate coated with asymmetric metal foils and the warpage of the printed circuit board prepared by it are increased, resulting in decreased reliability; using the cured low-modulus prepreg with the XY-CTE of less than or equal to 18 ppm/° C. can ensure that the deformations of the laminate coated with asymmetric metal foils and the printed circuit board prepared by it during use are not enough to affect normal use, which have a low warpage and good reliability.

The present application does not specifically limit the type of the metal foil, which may be selected from a metal foil used for printed circuit board materials.

The present application does not specifically limit the thickness of the metal foil, which may be selected from any thickness of the metal foil used for printed circuit board materials.

As a preferred technical solution of the present application, when one side of the laminate coated with asymmetric metal foils is coated with a metal foil, the metal foil coated on the side of the low-modulus prepreg has a thickness of 1.5-700 μm; for example, it may be 1.5 μm, 3 μm, 5 μm, 9 μm, 12 μm, 18 μm, 35 μm, 70 μm, 80 μm, 90 μm, 105 μm, 120 μm, 140 μm, 175 μm, 200 μm, 210 μm, 245 μm, 280 μm, 300 μm, 315 μm, 350 μm, 385 μm, 400 μm, 420 μm, 490 μm, 525 μm or 700 μm, etc.

As a preferred technical solution of the present application, when both sides of the one or at least two stacked low-modulus prepregs are coated with metal foils, the metal foils on both sides have a thickness difference of more than or equal to 5 μm; for example, it may be 5 μm, 8 μm, 10 μm, 12 μm, 15 μm, 18 μm, 20 μm, 22 μm, 25 μm, 28 μm, 30 μm, 32 μm, 35 μm, 38 μm, 40 μm, 42 μm, 45 μm, 48 μm, 50 μm, 52 μm, 55 μm, 58 μm, 60 μm, 65 μm, 70 μm, 75 μm, 80 μm, 85 μm, 90 μm, 95 μm, 100 μm, 110 μm, 130 μm, 150 μm, 170 μm, 190 μm, 200 μm, 210 μm, 230 μm, 250 μm, 270 μm, 290 μm, 300 μm, 310 μm, 330 μm, 350 μm, 370 μm, 390 μm, 400 μm or 410 μm, etc., preferably, more than or equal to 10 μm, more preferably, more than or equal to 18 μm, further preferably, more than or equal to 35 μm. When the thickness difference between the metal foils on both sides is more than or equal to 5 μm, the laminate coated with asymmetric metal foils will be warped, and selecting the low-modulus prepreg in the present application can effectively reduce warpage, or even completely eliminate warpage. As the thickness difference between the metal foils on both sides increases, the internal stress difference caused by the structural asymmetry is increasing, the laminate coated with asymmetric metal foils is easier to warp, and the more it shows that compared with the conventional prepreg, the low-modulus prepreg in the present application plays an obvious role in reducing or even completely eliminating warpage.

As a preferred technical solution of the present application, from the perspective of signal transmission loss and fine circuit processing capability, when both sides of the one or at least two stacked low-modulus prepregs are coated with metal foils, the thickness of the metal foil coated on one side of the one or at least two stacked low-modulus prepregs is preferably less than or equal to 35 μm (for example, it may be 35 μm, 33 μm, 30 μm, 28 μm, 25 μm, 22 μm, 20 μm, 18 μm, 15 μm, 12 μm, 9 μm, 6 μm, 5 μm, 3 μm, or 1.5 μm); from the perspective of current transmission and heat dissipation capacity, the thickness of the metal foil coated on the other side of the one or at least two stacked low-modulus prepregs is more than or equal to 70 μm (for example, it may be 70 μm, 80 μm, 90 μm, 105 μm, 120 μm, 140 μm, 175 μm, 200 μm, 210 μm, 245 μm, 280 μm, 300 μm, 315 μm, 350 μm, 385 μm, 400 μm, 420 μm, 490 μm, 525 μm, or 700 μm); from the perspective of processing capability of laminates coated with metal foils and printed circuit boards, the thickness of the metal foil coated on the other side of the one or at least two stacked low-modulus prepregs is further preferably 70-420 μm; further considering current transmission and heat dissipation capacity, processing capacity of laminates coated with metal foils and printed circuit boards, the thickness of the metal foil coated on the other side of the one or at least two stacked low-modulus prepregs is 140-420 μm.

As a preferred technical solution of the present application, the cured low-modulus prepreg has a T_{g} of more than or equal to 150° C., for example, it may be 150° C., 155° C., 160° C., 165° C., 170° C., 175° C., 180° C., 185° C., 190° C., 195° C., 200° C., 205° C., 210° C., 220° C., 225° C., 230° C., 235° C., 240° C., 245° C., 250° C., 255° C., 260° C., 265° C., 270° C., 275° C., 280° C., 290° C. or 300° C., etc.; preferably, more than or equal to 170° C., more preferably, more than or equal to 200° C., further preferably, more than or equal to 230° C., most preferably, more than or equal to 250° C.

The selection of T_{g} of the cured low-modulus prepreg in the present application is related to the operating temperature of the laminate coated with asymmetric metal foils and the printed circuit board prepared by it. When the operating temperature is higher than T_{g}, the cured prepreg is in a rubbery state, and the laminate coated with asymmetric metal foils and the printed circuit board prepared by it have a large deformation after being subjected to stress, affecting reliability. The operating temperature of the laminate coated with asymmetric metal foils and the printed circuit board prepared by it is generally more than or equal to 150° C., and therefore, in order to improve the modulus retention rate of the cured prepreg at high temperature, the T_{g} of the cured low-modulus prepreg in the present application is more than or equal to 150° C., preferably, more than or equal to 170° C., more preferably, more than or equal to 200° C., further preferably, more than or equal to 230° C., most preferably, more than or equal to 250° C.

In a second aspect, the present application provides a printed circuit board, and the printed circuit board includes at least one laminate coated with asymmetric metal foils in the first aspect.

Compared with the prior art, the present application has the beneficial effects below.

In the present application, by adjusting and controlling the modulus of elasticity of the cured prepreg less than or equal to 22 GPa, the obtained laminate coated with asymmetric metal foils has a relatively low warpage, ensuring the reliability of the printed circuit board prepared by it.

### DETAILED DESCRIPTION

The technical solutions of the present application are further described below through specific embodiments. Those of skill in the art should understand that the embodiments are only to help understand the present application and should not be regarded as a specific limitation of the present application.

The specifications of the prepregs used in examples of the present application are as follows.
Prepreg A: a modulus of elasticity after curing is 17 GPa, XY-CTE is 13 ppm/° C., and T_{g} is 270° C.;
Prepreg B: a modulus of elasticity after curing is 21 GPa, XY-CTE is 10 ppm/° C., and T_{g} is 270° C.;
Prepreg C: a modulus of elasticity after curing is 10 GPa, XY-CTE is 10 ppm/° C., and T_{g} is 170° C.;
Prepreg D: a modulus of elasticity after curing is 18 GPa, XY-CTE is 20 ppm/° C., and T_{g} is 150° C.;
Prepreg E: a modulus of elasticity after curing is 17 GPa, XY-CTE is 20 ppm/° C., and T_{g} is 270° C.;
Prepreg F: a modulus of elasticity after curing is 28 GPa, XY-CTE is 10 ppm/° C., and T_{g} is 270° C.;
Prepreg G: a modulus of elasticity after curing is 23 GPa, XY-CTE is 15 ppm/° C., and T_{g} is 270° C.;
Prepreg H: a modulus of elasticity after curing is 28 GPa, XY-CTE is 20 ppm/° C., and T_{g} is 270° C.; and
Prepreg I: a modulus of elasticity after curing is 17 GPa, XY-CTE is 15 ppm/° C., and T_{g} is 270° C.

The present application does not limit the thickness of the prepreg and the thickness of the glass fiber cloth. In order to facilitate comparison, the thickness of the above single prepreg is uniformly selected as 125 μm.

The performance test methods of the cured prepregs are as follows.

Sample preparation: 12 μm of copper foils are coated on both sides of 8 stacked prepregs and 1 prepreg respectively, and then placed in a hot press, cured at a temperature of 200° C. and a pressure of 30 kg/cm² for 90 min, so that the prepreg(s) is completely cured, copper foils are etched, and then laminates with a thickness of 1.0 mm and 0.125 mm are separately obtained.

Test method for copper foil thickness: refer to GB/T 29847-2013 test methods for copper foil used for printed boards 6.3.

Test method for modulus of elasticity: a laminate with a length of 76.2 mm, a width of 25.4 mm and a thickness of 1.0 mm is used as a sample, and measured by a material-testing machine with a span of 25.4 mm and a test speed of 0.76 mm/min. According to the formula, the maximum bending strength can be converted into a flexural modulus, that is, a modulus of elasticity, and a unit is GPa.

Test method for XY-CTE: a laminate with a length of 60 mm, a width of 4 mm and a thickness of 0.125 mm is used as a sample, the direction of glass fiber weft yarn is X, and the direction of glass fiber warp is Y, the sample is baked in an oven at 105° C. for 1 h, and then cooled to room temperature in a dryer. Thermal mechanical analysis method (TMA) is used to measure, a heating rate is 10° C./min, the temperature is raised from room temperature to 260° C., two heating operations are performed, and the sample is cooled to room temperature after a first heating operation, then the test sample is repositioned and subject to a second operation, and the result is a coefficient of thermal expansion in planar direction at the second heating from 50° C. to 130° C., and a unit is ppm/° C.

Test method for glass transition temperature (T_{g}): a laminate with a length of 60 mm, a width of 10 mm and a thickness of 1.0 mm is used as a sample, a dynamic mechanical thermal analyzer (DMA) is used to measure, a heating rate is 10° C./min, and the result is a transition peak temperature of tan δ, and a unit is ° C.

The specifications of the copper foils used in examples of the present application are as follows.
Copper foil A: a thickness of 12 μm;
Copper foil B: a thickness of 35 μm;
Copper foil C: a thickness of 105 μm; and
Copper foil D: a thickness of 210 μm.

### Examples 1-11 and Comparative Examples 1-4

Examples 1-11 and Comparative Examples 1˜4 respectively provide a laminate coated with asymmetric metal foils consisting of the low-modulus prepreg, and a metal foil which is coated on one side of the low-modulus prepreg or metal foils having different thicknesses which are coated on two sides of the low-modulus prepreg. The preparation method is as follows.

Two copper foils with different thicknesses were coated on both sides of the prepreg, or one copper foil was coated on one side of the prepreg, and then placed in a hot press, cured at a temperature of 200° C. and a pressure of 30 kg/cm² for 90 min, so that the prepreg was completely cured, and a laminate coated with asymmetric metal foils was obtained;

wherein types of the prepregs and copper foils are shown in Tables 1 and 2.

The warpage of laminates coated with asymmetric metal foils provided in Examples 1-11 and Comparative Examples 1-4 is subjected to test.

The warpage types of laminates coated with asymmetric metal foils are divided into bow and twist, and their definition and test method refer to IPC-TM-650 standard.

Bow is defined as: a deformation of a plate similar to a cylindrical or curved spherical shape, and for a rectangular copper foil plate, its four corners are located in the same plane.

Test method for bow: a convex side of a sample is placed upward on a test platform, and the maximum vertical distance between the sample and the platform is measured.

Twist is defined as: a deformation of a rectangular plate parallel to the diagonal direction, where one corner is not contained in the plane of the other three corners.

Test method for twist: a sample is placed on a test platform so that any three corners touch the platform, and the maximum vertical distance between the non-contact platform corner and the platform is measured.

The A-state warpage refers to the maximum value of bow or twist obtained by directly testing a sample without treatment, which is the A-state warpage.

The warpage after reflow soldering treatment refers to the maximum amount of bow or twist obtained by the test sample after reflow soldering treatment, which is the warpage after reflow soldering treatment, and the reflow soldering parameters are set to heat from 30° C. to 260° C., and then cool from 260° C. to 30° C. at a rate of 3° C./min.

The sample size of the laminate coated with asymmetric metal foils is 250 mm (warp)×300 mm (weft).

The results of the above tests are shown in Tables 1, 2 and 3.

TABLE 1

| | Example 1 | Example 2 | Example 3 | Example 4 | Example 5 | Example 6 |
|---|---|---|---|---|---|---|
| Prepreg | 1 × | 1 × | 1 × | 1 × | 1 × | 1 × |
| | prepreg | prepreg | prepreg | prepreg | prepreg | prepreg |
| | A | B | C | D | E | I |
| Upper copper foil | copper | copper | copper | copper | copper | copper |
| | foil A | foil A | foil A | foil A | foil A | foil A |
| Lower copper foil | copper | copper | copper | copper | copper | copper |
| | foil D | foil D | foil D | foil D | foil D | foil D |
| A-state warpage/mm | 0.1 | 0.4 | 0.1 | 0.6 | 0.56 | 0.15 |
| Warpage after reflow | 0.9 | 2.0 | 1.3 | 4.0 | 3.0 | 1.3 |
| soldering/mm | | | | | | |

TABLE 2

| | Example 7 | Example 8 | Example 9 | Example 10 | Example 11 |
|---|---|---|---|---|---|
| Prepreg | 1 × | 1 × | 1 × | 2 × | 1 × |
| | prepreg A | prepreg A | prepreg A | prepreg A | prepreg A |
| Upper copper foil | copper foil | copper foil | copper foil | copper foil | copper foil |
| | A | B | B | A | D |
| Lower copper foil | copper foil | copper foil | copper foil | copper foil | / |
| | C | C | D | D | |
| A-state warpage/mm | <0.1 | <0.1 | <0.1 | 0.1 | 0.15 |
| Warpage after reflow | 0.6 | 0.5 | 0.8 | 1.0 | 1.0 |
| soldering/mm | | | | | |

TABLE 3

| | Comparative | Comparative | Comparative | Comparative |
|---|---|---|---|---|
| | Example 1 | Example 2 | Example 3 | Example 4 |
| Prepreg | 1 × prepreg F | 1 × prepreg G | 1 × prepreg F | 1 × prepreg H |
| Upper copper | copper foil A | copper foil A | copper foil B | copper foil A |
| foil | | | | |
| Lower copper | copper foil D | copper foil D | copper foil D | copper foil D |
| foil | | | | |
| A-state | 10 | 6 | 7 | 15 |
| warpage/mm | | | | |
| Warpage | 15 | 12 | 13 | 20 |
| after reflow | | | | |
| soldering/mm | | | | |

It can be seen from the test results in Table 1 and Table 2 that the laminate coated with asymmetric metal foils using the cured low-modulus prepreg with a modulus of elasticity of less than or equal to 22 GPa has a low warpage, and the A-state warpage and the warpage after reflow soldering are less than 5 mm.

It can be seen from the test results in Table 3 that when the modulus of the cured prepreg is too high (Comparative Examples 1-4), the warpage of the laminate coated with asymmetric metal foils in A-state and after reflow soldering increases significantly, and is more than 5 mm, in which the warpage after reflow soldering is much larger than the A-state warpage.

Comparing Example 1 with Example 5, and Comparative Example 1 with Comparative Example 4, it can be seen that when the modulus and T_{g} of the prepreg are similar, the smaller the XY-CTE, the greater the ability of resist deformation, so it is helpful to reduce the warpage, especially warpage after reflow soldering; however, reducing the modulus of elasticity of the prepreg has a more obvious effect on the reduction of the amount of warpage.

The applicant declares that the above embodiments are only used to illustrate the technical solutions of the present application, but not to limit the scope of protection of the present application. Those of skill in the art should understand that any change or replacement within the technical scope in the present application, which can be easily thought by a person skilled in the art, all fall within the scope of protection and disclosure of the present application.

1-10. (canceled)

11. A laminate coated with asymmetric metal foils, which comprises one or at least two stacked low-modulus prepregs, and a metal foil which is coated on one side of the one or at least two stacked low-modulus prepregs or metal foils having different thicknesses which are coated on both sides of the one or at least two stacked low-modulus prepregs;
a modulus of elasticity of the cured low-modulus prepreg is less than or equal to 22 GPa.

12. The laminate coated with asymmetric metal foils according to claim 11, wherein a modulus of elasticity of the cured low-modulus prepreg is less than or equal to 20 GPa.

13. The laminate coated with asymmetric metal foils according to claim 11, wherein a modulus of elasticity of the cured low-modulus prepreg is more than or equal to 5 GPa.

14. The laminate coated with asymmetric metal foils according to claim 11, wherein an XY-CTE of the cured low-modulus prepreg is less than or equal to 18 ppm/° C.

15. The laminate coated with asymmetric metal foils according to claim 11, wherein both sides of the one or at least two stacked low-modulus prepregs are coated with metal foils, and the metal foils on both sides of the one or at least two stacked low-modulus prepregs have a thickness difference of more than or equal to 35 μm.

16. The laminate coated with asymmetric metal foils according to claim 11, wherein both sides of the one or at least two stacked low-modulus prepregs are coated with metal foils, a thickness of the metal foil coated on one side of the one or at least two stacked low-modulus prepregs is less than or equal to 35 μm, and a thickness of the metal foil coated on the other side is more than or equal to 70 μm.

17. The laminate coated with asymmetric metal foils according to claim 11, wherein a thickness of the metal foil coated on one side of the low-modulus prepreg is less than or equal to 35 μm, and a thickness of the metal foil coated on the other side is 70-420 μm.

18. The laminate coated with asymmetric metal foils according to claim 11, wherein one side of the one or at least two stacked low-modulus prepregs is coated with a metal foil, and the metal foil has a thickness of 1.5-700 μm.

19. The laminate coated with asymmetric metal foils according to claim 11, wherein the cured low-modulus prepreg has a T_{g} of more than or equal to 150° C.

20. A printed circuit board, wherein the printed circuit board comprises at least one laminate coated with asymmetric metal foils according to claim 11.
